(19) United States
(12) Patent Application Publication
(10) Pub. No.: US 2024/0128115 A1
(43) Pub. Date: Apr. 18, 2024

(54) RESOURCE MANAGEMENT WITH TIME AND EXPENSE TRACKING

(71) Applicant: Florida Power & Light Company, Juno Beach, FL (US)

(72) Inventor: Heidi Elizabeth Bailey, West Palm Beach, FL (US)

(73) Assignee: VueReal Inc., Waterloo (CA)

(21) Appl. No.: 18/390,306

(22) Filed: Dec. 20, 2023

Related U.S. Application Data
(63) Continuation of application No. 17/915,561, filed on Sep. 29, 2022.
(60) Provisional application No. 63/002,046, filed on Mar. 30, 2020.
(60) Provisional application No. 63/057,238, filed on Jul. 27, 2020.

(51) Int. Cl. H01L 21/683; H01L 21/67; H01L 23/544

(52) U.S. Cl. CPC H01L 21/6835; H01L 21/67259; H01L 23/544; H01L 2221/68309; H01L 2223/54426

(57) ABSTRACT

Method and system that operates on a server include a time and expense management interface for capturing time and expense reporting. The time and expense reporting is for utility distribution systems, such as electrical power distribution and/or transmission systems, cellular, telecommunications, cable TV, water and sewer, natural gas, and others. These utility distribution systems include a large number of devices or objects that are distributed across a big geographic area. In one example, the authorization to submit the invoice for portions of the mobilization work order that have completed the approval process includes only authorization to submit the invoice for those portions of the mobilization work order i) not already paid or ii) that have been previously submitted and completed the approval process. The invention helps to document time and expense for government agencies, such as public utility commissions. This documentation maybe used with setting special charges on customer invoices.

### FIELD OF THE DISCLOSURE

The present disclosure generally relates to resource management and, more specifically, to time and expense tracking of workers being mobilized from one geographic area to another as part of a work order.

### BACKGROUND

Organizations that maintain and operate various utility distribution systems, such as, electrical power distribution and/or transmission systems, cellular, telecommunications, cable TV, water and sewer, natural gas and others, are generally responsible for maintaining and operating a large number of devices or objects that are distributed across a large geographic area. In order to repair distribution systems, organizations will hire private contractors and other utility operators to help install, repair, and restore distribution systems. This is especially true after large disruptive events, such as, winter storms, hurricanes, tornadoes, floods, fires, and earthquakes. Keeping track of repair teams is often done by paper and pencil because cellular and other services may not operate reliably, particularly when the electric power distribution system is down. Addressing issues with particular components, parts, and subsystems and maintaining the operations of utility systems is a challenge. It can also be a challenge when documenting time and expense for government agencies, such as public utility commissions.

More broadly, in addition to utility distribution systems, organizations that manage, track, and pay resources for all kinds of emergencies face similar challenges. These include wildland firefighters, search and rescue, delivering aid from humanitarian organizations, and more. These organizations, like utilities, must organize both internal and external resources to respond to a situation in which the teams must be accounted for both logistically and financially.

### SUMMARY OF THE INVENTION

The present invention provides a novel system and method for capturing time and expense reporting. The time and expense reporting use includes utility distribution systems, such as, electrical power distribution and/or transmission systems, cellular, telecommunications, cable TV, water and sewer, natural gas and others. These utility distribution systems include a large number of devices or objects that are distributed across a big geographic area.

The present invention replaces paper and pencil systems that were necessary after a large disruptive event, such as such as, winter storms, hurricanes, tornadoes, floods, fires, and earthquakes because power was not working reliably and cellular communications and other wireless communication is down.

A combination of business rules on a portable electronic device and rules on the server helps to ensure that time and expense reporting is accurate and timely. The user interface may use color schemes to help the crew understand when business rules are in compliance for time and expense entries. Crew identifiers, such as facial recognition, finger print recognition, and near-field communications tags, are used to authenticate the crew working on repairs. Pictures of vehicles, including identifiers such as VINs and GPS coordinates, helps to ensure accurate records. Authorized GPS locations may be tied to equipment location, staging areas, and other known GPS coordinates. Rosters may be pre-populated on the portable electronic device ahead of time from a central server. This pre-population reduces transcription errors for worker crew member's names. Further, the pre-population reduces duplicate entries of names, such as a given legal name and nicknames, which are often counted twice.

In one example the computer-implemented method and system for time and expense management. A server is used to provide a time and expense management interface to track a plurality of crews to perform work in a target geographic location. The crew-specific information includes an identifier of at least one or more members of a selected crew in the plurality of crews. The crew-specific information is received from a representative for each of the plurality of crews, wherein the crew-specific information includes the number of crew members and skill type of each crew member and vehicle information.

The system sends a mobilization work order from the server to a portable electronic device associated with the selected crew. Next, the server receives a mobilization start time by the server from the portable electronic device used by the crew.

In one example, receiving the mobilization start time includes automatically sending the mobilization start time in response to the portable electronic device moving outside a defined geographic start region.

The server calculates an estimated mobilization time period to have the selected crew relocate from its current geographic position to the target geographic location. Based on the portable electronic device associated with the selected crew being in proximity to a wireless communication infrastructure in the target geographic location, it automatically sends a mobilization end time to the server from the portable electronic device. Next, based on receiving the mobilization end time, the server automatically calculates an actual elapsed mobilization time from the start time.

In one example, prior to automatically sending the mobilization end time to the server from the portable electronic device, the portable electronic device cannot connect to a wireless telecommunications network due to necessary infrastructure being unavailable, and during the actual mobilization time, any information received is locally cached on the portable electronic device before automatically sending the mobilization end time to the server.

The server verifies the actual elapsed mobilization time with the estimated mobilization time in accordance with one or more business rules. Based on one or more business rules being verified, the elapsed mobilization time for the selected crew as part of the mobilization work order is placed into an approval process, and the status of the selected crew is changed from a mobilization mode to an arrival mode. Based on the approval process being complete, sending from the server to the portable electronic device, an authorization to submit an invoice for portions of the mobilization work order that have completed the approval process. Otherwise, the system automatically begins a dispute escalation process if a business rule is not satisfied.

In one example, the authorization to submit the invoice for portions of the mobilization work order that have completed the approval process includes only authorization to submit the invoice for those portions of the mobilization work order i) not already paid or ii) that have been previously submitted and completed the approval process.

The present invention helps to document time and expense for government agencies, such as public utility commissions. This documentation is often used to assist with setting special charges on customer invoices.

The process continues by sending a site assignment order from the server to a portable electronic device associated with the selected crew. An en-route start time is received by the server from the portable electronic device. The server calculates an estimated en route time period to have the selected crew relocate from its current geographic position to a site in the site assignment order. Based on the portable electronic device associated with the site being in proximity to a wireless communication infrastructure in the site, it automatically sends an en route end time to the server from the portable electronic device. Based on receiving the en route end time, automatically calculating by the server, an actual elapsed en route time from the en route start time. The server verifies the actual elapsed mobilization time with the estimated en route time in accordance with one or more business rules. Based on one or more business rules being verified, automatically authorize the elapsed en route time for the selected crew as part of the site order and change the status of the selected crew from an en route mode to a site arrival mode.

### BRIEF DESCRIPTION OF THE DRAWINGS

The accompanying figures, where like reference numerals refer to identical or functionally similar elements throughout the separate views, and which together with the detailed description below are incorporated in and form part of the specification, serve to further illustrate various embodiments and to explain various principles and advantages all in accordance with the present disclosure, in which:

FIG. 1 illustrates an electricity distribution system, according to an example;

FIG. 2 illustrates major software components of the time and expense system on handheld devices and communicating with computer server, according to an example;

FIG. 3 is a table of example data for time and expense tracking, according to an example;

FIG. 4 is a flow of the time and entry process, according to an example;

FIG. 5 is a flow of a vendor submitting a proposal, according to an example;

FIG. 6 is a flow of a vendor submitting a proposal, according to an example;

FIG. 7 is a flow of a vendor creating teams, according to an example;

FIG. 8 is a flow of a vendor starting and stopping travel, according to an example;

FIG. 9 is a flow of a reviewing time and expense for the production lead, according to an example;

FIG. 10 is a flow of a reviewing time and expense for the travel coordinator, according to an example;

FIG. 11 through FIG. 13 is a flow of a pre-storm, site, commitments, and team setup, according to an example;

FIG. 14 through FIG. 15 is a flow of mobilization, according to an example;

FIG. 16 is a flow of processing, according to an example;

FIG. 17 is a flow of working, according to an example;

FIG. 18 is a flow of demobilization, according to an example;

FIG. 19 is a flow of post-storm, according to an example; and

FIG. 20A and FIG. 20B is a flow of authorization to submit invoices based on mobilization work order, according to an example;

FIG. 21A, FIG. 21B and FIG. 22 are interactive user interface screens of the time and entry process of FIG. 1-20, according to an example; and

FIG. 23 is a block diagram of an example portable electronic or handheld device.

### DETAILED DESCRIPTION

### Example Embodiments

As required, detailed embodiments are disclosed herein; however, it is to be understood that the disclosed embodiments are merely examples and that the systems and methods described below can be embodied in various forms. Therefore, specific structural and functional details disclosed herein are not to be interpreted as limiting but merely as a basis for the claims and as a representative basis for teaching one skilled in the art to variously employ the disclosed subject matter in virtually any appropriately detailed structure and function. Further, the terms and phrases used herein are not intended to be limiting but rather, to provide an understandable description.

The terms “a” or “an”, as used herein, are defined as one or more than one. The term plurality, as used herein, is defined as two or more than two. The term another, as used herein, is defined as at least a second or more. The terms “including” and “having,” as used herein, are defined as comprising (i.e., open language). The term “coupled,” as used herein, is defined as “connected,” although not necessarily directly and not necessarily mechanically. The term “configured to” describes hardware, software, or a combination of hardware and software that is adapted to, set up, arranged, built, composed, constructed, designed or that has any combination of these characteristics to carry out a given function. The term “adapted to” describes hardware, software or a combination of hardware and software that is capable of, able to accommodate, to make, or that is suitable to carry out a given function.

The term “vendor” is used interchangeably with “employee”, and “contractor”, who are performing services under a work order.

The term “work order” is usually a task or a job for a customer that can be scheduled or assigned to someone. Such an order may be from a customer request or created internally within the organization. Work orders may also be created as follow-ups to inspections or audits. A work order may be for products or services.

As required, detailed embodiments are disclosed herein; however, it is to be understood that the disclosed embodiments are merely examples and that the systems and methods described below can be embodied in various forms. Therefore, specific structural and functional details disclosed herein are not to be interpreted as limiting but merely as a basis for the claims and as a representative basis for teaching one skilled in the art to variously employ the disclosed subject matter in virtually any appropriately detailed structure and function. Further, the terms and phrases used herein are not intended to be limiting but rather to provide an understandable description.

### Utility Distribution System

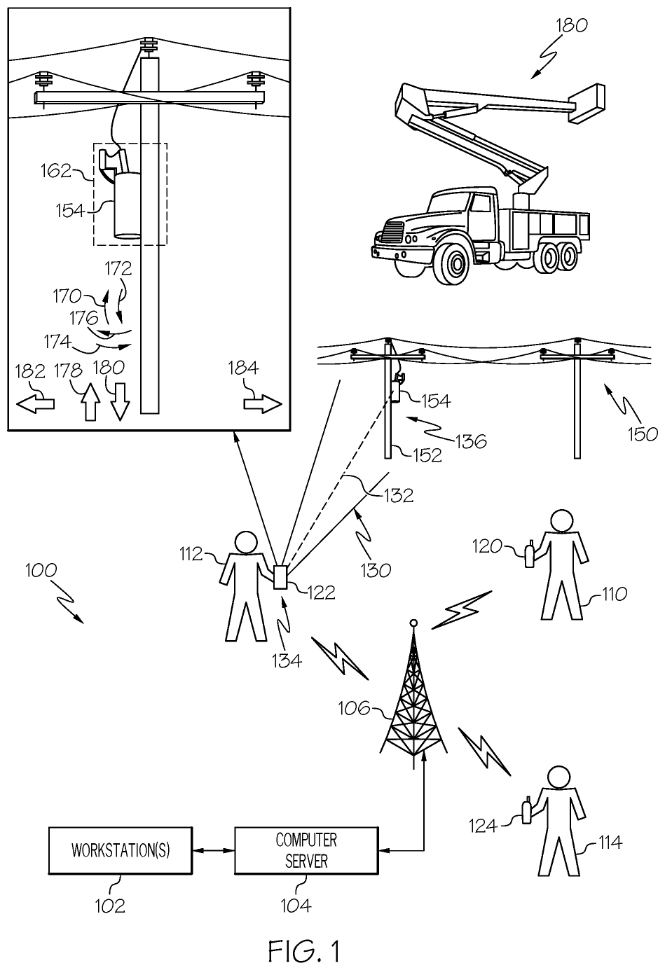

FIG. 1 illustrates a utility distribution system 100, according to an example. This is example is an electric utility distribution system, however, the present invention is applicable to other distribution systems as well, including cellular, telecommunications, cable TV, water and sewer, natural gas, wildland firefighting, and others. It is to be understood that various implementations are able to include multiples of the illustrated components as well as other components or fewer components than are illustrated in this example.

The utility distribution system 100 includes at least one computer server 104 that controls, coordinates, otherwise facilitates, or combinations of these, the operation of a time management system. The computer server 104, for example, maintains databases, including workers or members 110, 112, 114 of a given work crew, their images, and business rules. The computer server 104 in one example, receives information from members 110, 112, 114 of a given work crew and performs other functions. The computer server 104 sends customized business rules business rules, images of the members of the crew, and other information related to the members of the crew to portable communications devices 120, 122, 124 of the members 110, 112, 114. The computer server 104 presents information to operators (not shown). In some examples, parts or all of several of the methods described below are performed by the computer server 104 or a similar computing apparatus.

One or more workstation(s) 102 provide a user interface for operators to interact with the computer server 104 and communicate with members 110, 112, 114 of a given work crew. In some examples, the workstation(s) 102 include graphical displays that are able to present images, videos, alphanumeric information, other information, or combinations of these. Further, the workstation(s) 102 in some examples include facilities to implement audio communications with members 110, 112, 114 of a given work crew. In various examples, an operator at workstation(s) 102 is able to provide indications of the geographic location for the observation of selected object, and provide ratings for observation data received from members 110, 112, 114 of a given work crew. The computer server 104, in this example, is connected to a wide area wireless communications system 106. The wide area wireless communications system depicted in this example is able to include various components, such as publicly available cellular data communications, other wireless communications, or combinations of these. The wide area wireless communications system 106 in some examples, includes a number of radio transmission towers and transceivers to allow wireless communications over a wide area.

An example number of members 110, 112, 114 of a given work crew who each have a portable communications device. In an example, each portable communications device 120, 122, 124 has a camera along with other components to support the operation of the below-described systems and methods. In this example, a first member 110 has a first communications device 120, a second member 112 has a second communications device that has a member camera 122, and a third member 114 has a third communications device 124. In operation, utility distribution system 100 is able to have any number of members with communications devices. For example, the wide area wireless communications system 106 supports communications between the computer server 104 and the communications devices held by the various members. In general, the members are able to have similar or different communication devices, each with a camera.

The communications devices for each member, in an example, can receive information from the computer server 104, capture observation data such as images, videos, other observation data, or combinations of these, communicate the observation data back to the computer server 104, and support interactions between the member and an operator at a workstation(s) 102 working via the computer server 104. In some examples, the communications devices, such as the first communications device 120, the second communications device that has a member camera 122, and the third communications device 124, each have location equipment to determine and report the present geographic location of that device, and thus the present geographic location of the member associated with that device. In some examples, the location equipment sends reports of the present geographic location that is determined by the location of its communications device to the computer server 104 for use in determining which members are near a geographic location for observation.

In the following discussion, interactions between the computer server 104 and the members 110, 112, 114 are conducted through a respective communications device that is associated with each member. In an example, each communications device has a camera that is able to capture images, such as images of an object to be observed. In general, a description of sending any information, instructions, offers, other data, or combinations of these to a member is referred to as sending such information, instructions, offers, other data, or combinations of these to a member camera that is associated with that member.

It is important to note that the communication devices 120, 122, and 124 are configured to work completely “offline” in the event that communications are not available with computer server 104. This is important because disruptive events, such as hurricanes, often disrupt power distribution systems. The software as will be discussed further below on the communication devices 120, 122, and 124 is designed to work offline and synchronize back up with the computer server 104 at a later time, when communication systems are available.

The utility distribution system 100 depicts a portion of an electrical distribution system 150. The depicted portion of the electrical distribution system includes a pole 152 that has a pole-mounted transformer 154. In an example, the three (3) members depicted in the members 110, 112, 114 are in the vicinity of pole 152. For example, the vicinity of the pole is defined as being a threshold distance from the pole 152. In general, the present camera location 134 and the object location 136 are three-dimensional location values that are precisely determined, such as by GPS receivers. Moreover, communication devices 120, 122, and 124 may include camera pose angle determination equipment, such as a compass (not shown) to determine an azimuth direction of the pose angle 132 and an accelerometer (not shown) to determine elevation angles 130 of the pose angle 132. Also shown is a utility truck 180. In this example, the utility truck 180 is a bucket truck, and it includes identifying features, such as a license plate, DOT number, or fleet number, to help identify it in images.

In this example, transformer 162 is mounted on pole 152 as shown. Using the camera on communication device 122, member 112 can perform camera movement up 170, camera movement down 172, camera movement right 174, and camera movement left 176. In addition, other photographic techniques, such as image-stitching to create panoramic horizontal 182, 184 and vertical 178, 180 are possible.

### Major Software Components

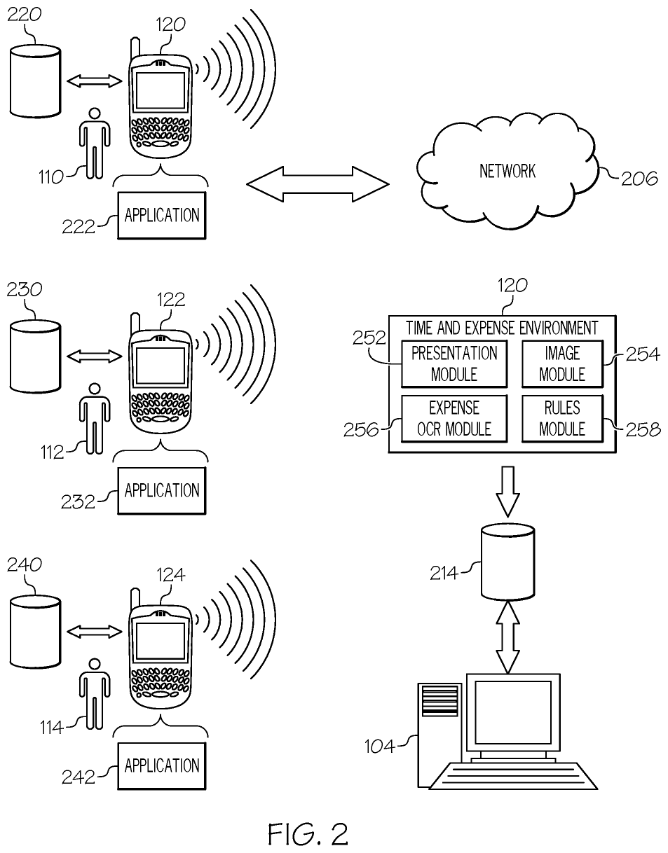

FIG. 2 illustrates software components of a time and expense major system on the handheld device and communicating with computer server 104 of FIG. 1. The callout item numbers beginning with “1” refers to identical or functionally similar elements previously described above with reference to FIG. 1. More specifically, the communication devices 120, 122, and 124 each include at least one database 220, 230, 240 and an app or application 222, 232, 242. The software app can be a web browser that interfaces with a portal. One example of a software app with the backend infrastructure for electrical utility repair is the StormForce™ system created by the NextEra Energy. The database 214 includes several major software modules 250 as follows:
Presentation Module 252—enables the user 120, 122, 124 to interact with various screens as further described below.
Image Module 254—which interfaces with cameras on the communication devices 120, 122, 124 to document the faces of the members, the materials, the receipts, and the vehicles being used. The image module includes facial recognition software for validating a worker. The image module may also include object recognition software to help identify components of the utility distribution system. Further, the image module may include character recognition software to allow serial numbers, licensing plates and other characters to be recognized.
Expense OCR module 256—which includes optical character recognition (OCR) software for analyzing an image of a receipt, and reading barcodes and OR codes. The software tallies items on a receipt and compares the tally to the total of the receipt to ensure each item listed matches the total sum.
Rules Module 258—which includes business and business rules for each member, each crew, and subcategories such as work time (WT), overtime (OT), and double time (DT), for activities such as working, traveling, and standby.

It is important to note that although reference is made to software apps on communication devices, the present invention can be implemented as a web-based interface presenting a series of webpages to the user as well. The webpages, like the app, may be designed to cache data and apply some rules locally in the event communications between the communication devices and the webserver is not available.

### Data Structure

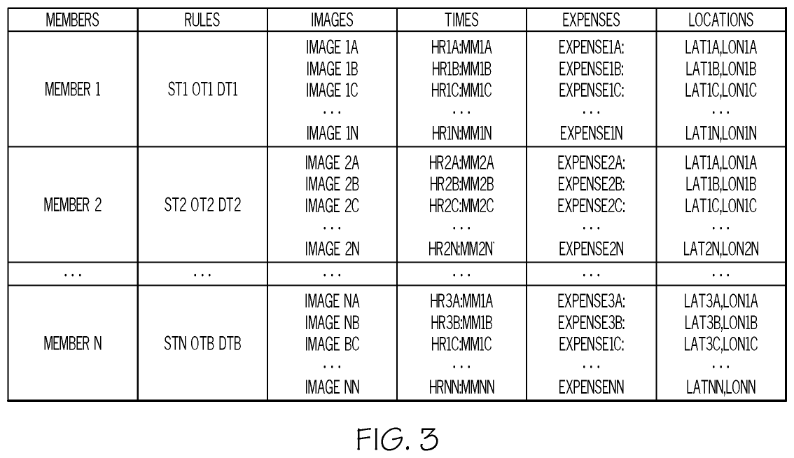

FIG. 3 is a table 300 of example data for time and expense tracking, according to an example. The table includes rows for each member 1, member 2, through member N. In table 300 the data includes rules for Standard Time (ST) or Work Time (WT), Overtime (OT), and Double Time (DT). These rules may include authorized members or workers, authorized start date and end date, authorized location(s), authorized maximum Standard Time (ST) per day, per week, per pay period, maximum overtime (OT) per day, per week, per pay period, Double Time (DT) per day, per week, per pay period, caps on expenses per day, per week, per pay period, authorized job descriptions, authorized expense categories and more.

### Flow Diagrams and User Interface Screens

The present disclosure generally relates to tracking time and expense and, more specifically, to tracking time and expense of contract workers installing, repairing, and restoring utility distribution systems.

Based on a series of customizable business rules, the system automatically calculates different types of hourly pay rates, including mobilization pay rates, working pay rates, holiday pay rates, and overtime pay rates. This automatic calculation eliminates steps in the review process.

The present invention is designed with several major groups as follows: 1) Administrators, 2) Resource Planners, 3) Travel Coordinators, 4) Vendors, 5) Team Leads, 6) Logistics, 7) Section Chiefs, 8) Program Leads, and 9) Mobilization Leads. Note that the system may be implemented with more or fewer major groups.

### System Administrators

The present invention assists the system administrators in creating an overall event, such as a storm event.

### Resource Planners

The present invention assists the resource planner in interacting with vendors to secure necessary resources for a storm event. Actions include:
Create commitments
Assist vendors with responding to commitments
Approve commitments
Maintain storm information on vendor accounts (short code, resource types, primary contacts)
Select sites to use for a storm event
Create Production Lead (PL) teams
Assign PLs to manage teams
Assign teams to sites based on damage or anticipated damage
Reallocate teams to sites as work is completed
Release teams at the conclusion of an event.

Common Process Issues: Assigning key Resource: If the resource name is not available in “Resource to Assign,” the resource planner will need to add/modify the contact with the correct storm role. Travel Orders: If the resource planner creates a new travel order with an earlier date than the original, the system will cancel the original travel order

### Vendors

The present invention assists the vendor in providing teams and invoices for storm events, include:
Maintain contacts
Respond to commitments
Create teams
Assist team leads with time and expense entry
Review and submit time and expenses to the Utility Company for payment
Generate Invoices and submit them for payment

### Travel Coordinator

The present invention assists the Travel Coordinator in interacting with vendors to create teams and communicate with team leads throughout a storm event. Actions include:
Assist vendors with creating teams
Document time and expense variations reasons
Monitor travel
Communicate issuance of work orders to travel
Assist team leads with time entry

Common Process Issues: A team will not be auto-approved if it has more than 30 people on the team, if they do not have a team lead, or if the team lead does not have an email. Contingent functionality will group teams that need to travel together. All teams grouped in a contingent will display a contingent name. Once grouped, the team must travel together. Once created, contingents may be edited to add or remove teams.

### Production Leads

The present invention assists the Production Leads in managing resources and assets at the sites and distributing work. Actions include:
Review resource counts assigned to the site
Maintains PL assignments systematically
Automatically moves PL with team location reassignment
Tags timesheets and expenses with assigned PL for approval flow
Approve time and expense (role dependent)

### Team Leads

The present invention assists Team Leads in managing that team and ensures time and expenses are captured daily. Actions include:
Manage teams
Work location assignment notification
Lodging assignment notification
Enter timesheets and expenses

### Resource Planner

The present invention assists the Resource Planner in assigning and allocating teams to work locations. Time and expense approvals are dependent on management at the work location, so proper assignment assists with proper time and expense approval routing. Actions include:
Resource Allocation to work sites
The site at capacity notification
Lodging assignments based on work location

### System (Automated Tasks)

The present invention uses business rules that can automatically route, authorize, and change the flow of many tasks. The system, for example, may use customizable business rules to determine if travel time is within a settable threshold, and if the elapsed time and/or expense is below a settable threshold, the travel time is automatically authorized.

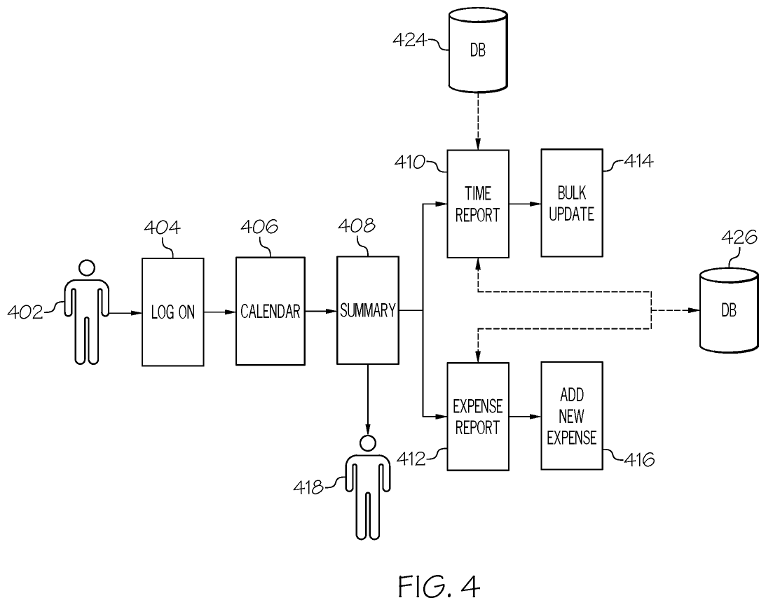

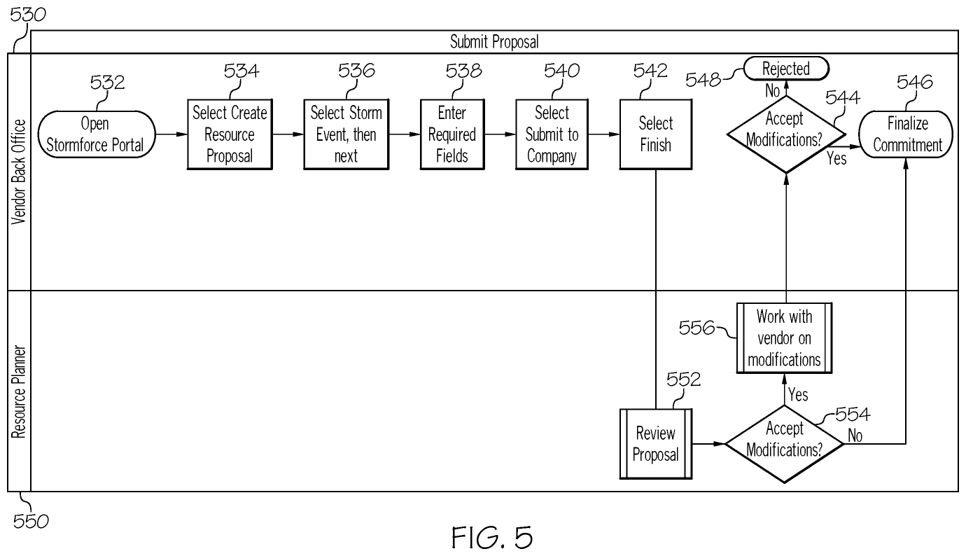

FIG. 4 is a flow of the time and entry process, according to an example and more details in FIG. 5 through FIG. 20.

The overall flow shown in FIG. 4 starts from the left side with the Team Lead 402 of a given crew logging in 404 and being presented with a calendar screen 406. A summary page 408 is shown before the time entries and/or expense entries are submitted for review by Project Lead 418, to server 104 coupled to database 424. This calendar screen 406 and summary page 408 is further illustrated in FIG. 5. Time entries 410 and expense entries 412 screens for review on server 104 are shown. Prior to approval by the PL, one or more internal rules may be implied to ensure the crew member's time entries are within the bounds of the rules set, as shown in the following figures. Once approved by Production Lead (PL) 418 these may be stored in the same database 424 or another database 426 as shown. In one example, the first database 424 is a Resources for Emergency Deployment (REDi) database that contains information to manage resources, commodities, and people which communicate with the application. The second database 426 is Contractor Time and Expense (CTE) Database 426, for collecting and storing all information related to contractor time entries through applications 222, 232, and 242.

### Flow of Proposal Commitment

Turning now to FIG. 5 is a flow of a vendor submitting a proposal, according to an example. Shown are the processes for vendor 530 and resource planner 550. In step 532, vendor 530 opens up 532 the software portal 250 on their electronic device, e.g., phone, tablet, laptop, or desktop computer, and navigates in the presentation module 252 to “create resource proposal.” The process continues to step 534. In step 534, vendor 530 creates a resource proposal and enters the proposal type in step 536. In this example, the type of proposal is a storm event for use by a public utility when using vendors to restore a power grid. Required fields in the portal 250 are filled in by vendor 530. Required fields 538 may include the size of crews, types of services, the experience level of each crew member, available equipment, and other information. Vendor 530 selects “submit” 540 to provide the proposal to portal 250 and “finish” 542. The proposal is automatically queued into the resource planner 550 for review 552. If the proposal is accepted in step 554, the commitment is finalized in step 546. Otherwise, if modifications are needed in step 544, the resource planner works with vendor 530 on modifications in step 556. Vendor 530 in step 544 either accepts the modifications in step 544 or rejects the commitment in step 548.

### Vendor Response to Company Commitment

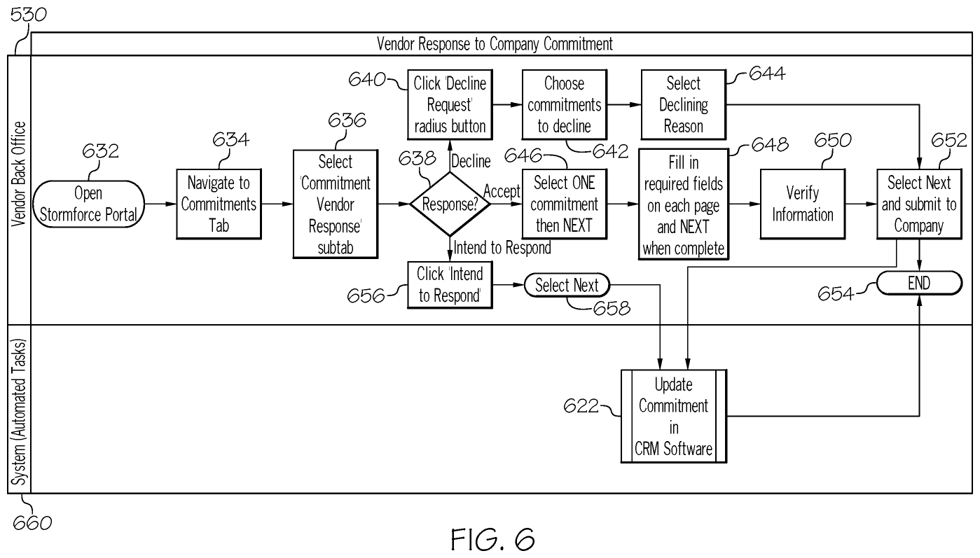

FIG. 6 is a flow of a vendor submitting a proposal, according to an example. Shown are the processes for vendor 530 and system (automated task) 660. Vendor 530 opens up 632 the software portal 250 on their electronic device, e.g., phone, tablet, laptop, or desktop computer, and navigates in the presentation module 252 over to the “commitments tab” 634 and desired sub-tab 636. The process flows to step 638, in which three possible paths are taken. The first path is that vendor 530 declines 642 the commitment in step 640, selects the reason for declining, e.g., previous commitment or starting zip code has changed 644, and proceeds to step 652 as shown. The second path from step 638 is that vendor 530 intends to respond in step 656, selects next in step 658, the status of the commitment is updated in the CRM software as a system (automated task) 622, and the process ends in step 654. Otherwise, the third path, vendor 530 accepts the commitment in step 646. Vendor 530 fills in all the required fields 648, information verified 650, submitted 652 to the company, and the process ends in step 654.

### Vendor Creates Teams

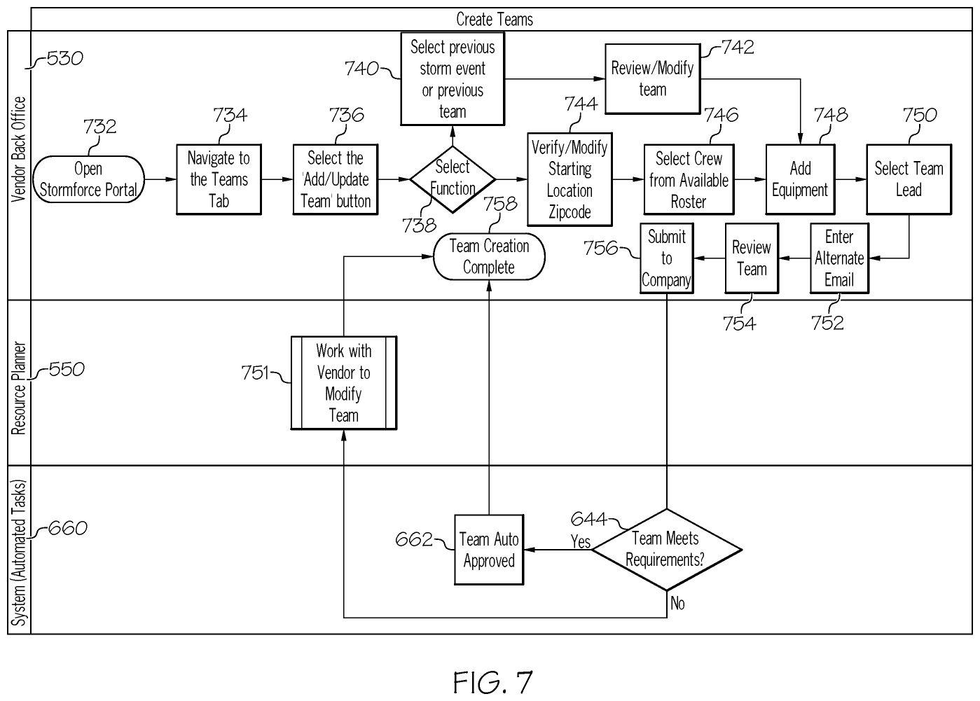

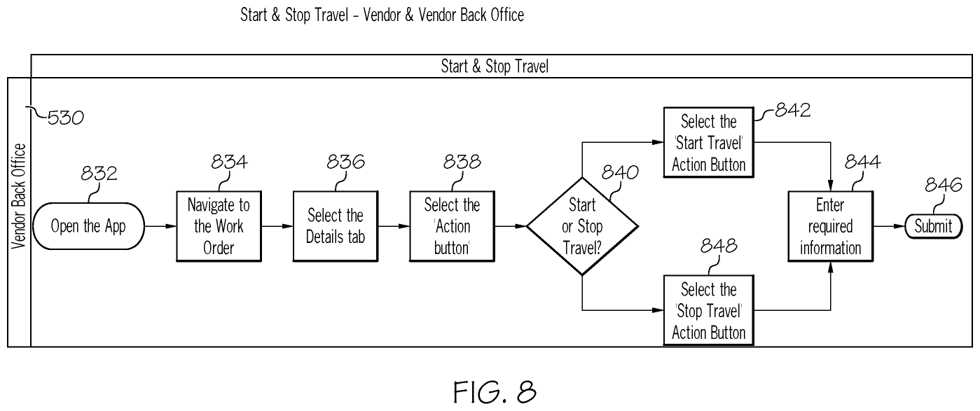

FIG. 7 is a flow of a vendor creating teams, according to an example. Shown are the processes for vendor 530, resource planner 550, and system (automated task) 660. Vendor 530 opens up 732 the software portal 250 on their electronic device, e.g., phone, tablet, laptop, or desktop computer, and navigates in the presentation module 252 over to the “teams tab” 734 and add/update button 736. In step 738, a test is made if this is a previous team. In the event the previous team is set up, the process continues to step 740 to select one of the previous teams, review/modify team 742 and equipment 748 as shown. Otherwise, in the event that it is not a previous team, the process continues to step 754, where the starting location zip code is entered 744, a crew is selected from roster 746, add equipment 748, a team lead is selected 750, an alternate email 752, the review of entries 754, and submit to company 756. The system (automated tasks) 660 uses business rules to determine if the team meets requirement 644. In the case that the team meets requirements, the team is auto-approved for step 662, and the team creation is complete for 758. Otherwise, in the case that the team does not meet the requirements in step 644, the process is directed to the resource planner 550 to work with vendor 520 to modify the team 751 before proceeding to team creation complete 758.

### Vendor Start and Stop Travel

FIG. 8 is a flow of a vendor starting and stopping travel, according to an example. Shown are the processes for vendor 530. Vendor 530 opens up 832 the software portal 250 on their electronic device, e.g., phone, tablet, laptop, or desktop computer, and navigates in the presentation module 252 over to the “work order” 834 and select details tab 836, select action button 838. A test is made 840 on whether this is the start or stop of travel. In the event it starts travel, the process flows to start travel action button 842 and enter the required information 844, and the process ends at submit 846. Otherwise, in the case that this is a stop travel, the process flows to the stop travel button 848 and enters the required information 844, and the process ends at submit 846.

### Review Time and Expense for Production Lead

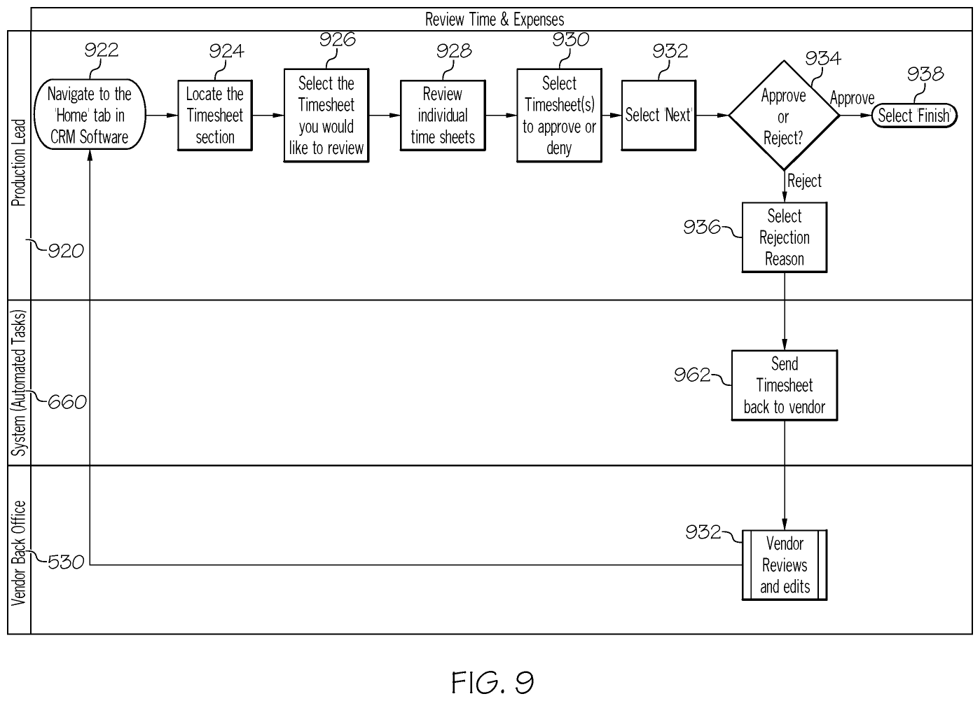

FIG. 9 is a flow of reviewing time and expense for the production lead 930, according to an example. Shown are the processes for vendor 530, system (Automated tasks) 660, and production lead 920. The production lead 920 opens up 832 the software portal 250 on their electronic device, e.g., phone, tablet, laptop, or desktop computer, and navigates in the presentation module 252 over to the “home tab” 922 and select locate time sheet 924, select timesheet to review action 926. Individual times sheets 928 are selected 930, 932, approved or rejected 934. In the case of approval, the system finishes in step 938. In the case the timesheet is rejected, the reason is selected in step 936, and the denied timesheet is sent back to vendor 530 in step 962. Vendor 530 reviews and revises the timesheet, and the process returns to step 922.

### Review Time and Expense for Travel Coordinator

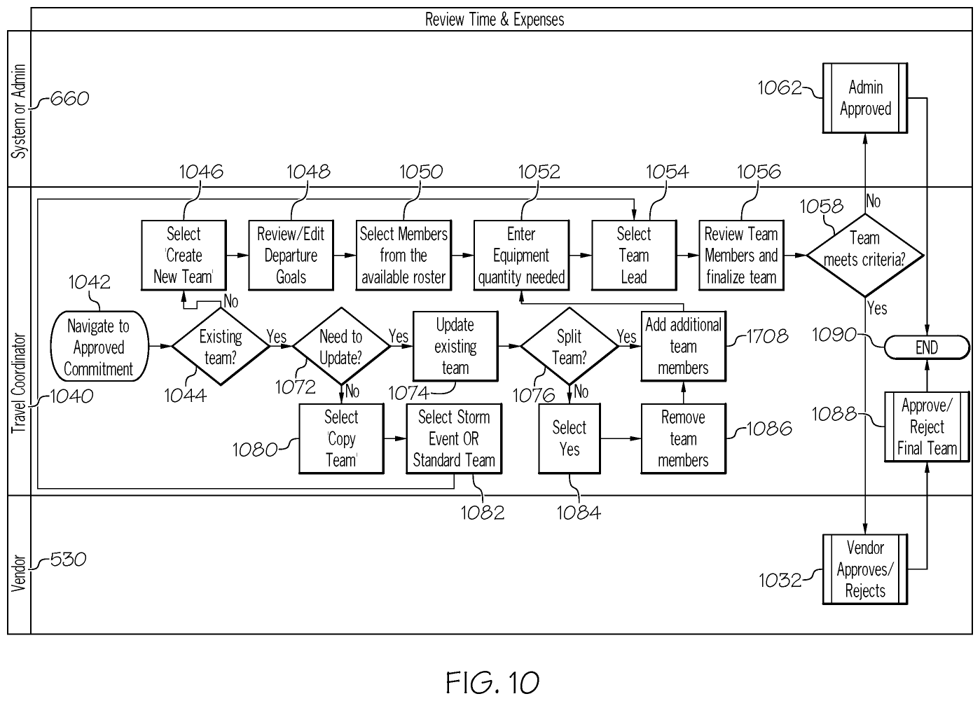

FIG. 10 is a flow of reviewing time and expense for the travel coordinator 1040, according to an example. Shown are the processes for vendor 530, system (automated tasks) 660, and production lead 920. The travel coordinator 1040 opens up the software portal 250 on their electronic device, e.g., phone, tablet, laptop, or desktop computer, and navigates in the presentation module 252 over to the “approve commitment” 1042. A determination is made if it is an existing team in 1044. If there is an existing team, a test 1072 is made to determine if teams need to be updated. If the team does not need to be updated, the process continues to update the existing team 1074. The process flows into a test on whether the teams should be split 1076. Even if the team should not be split, the process determines if team members need to be removed in steps 1084 and 1086 and if any additional member should be added in 1708. Otherwise, in the case that the team is not split 1076, the process continues to step 1708 to add any additional members in step 1708. The process continued to step 1052.

In the case where the team does not need to be updated in step 1080, the process continues to step 1080, and the storm event or standard team is selected in 1082. The process flows to step 1054, select team lead, as further described below.

In step 1044, in the case that there is not an existing team, the process continues to step 1046 to create a new team. The departure goals are reviewed in step 1048, the members of the roster are reviewed in step 1050, and the quantity of equipment needed is 1052. The select teams lead in step 1054 is to review team members and finalize the team. A test is made if teams meet criteria 1058. In the case the team meets the criteria, the process flows to system admin 660 for admin approval 1062 and ends in step 1090. Otherwise, in the case the team does not meet the criteria, the process has the vendor 530 approve or reject 1032 and the flows to travel coordinator 1040 for approval or reject final team 1088.

### Pre-Storm Site, Commitments & Team Setup

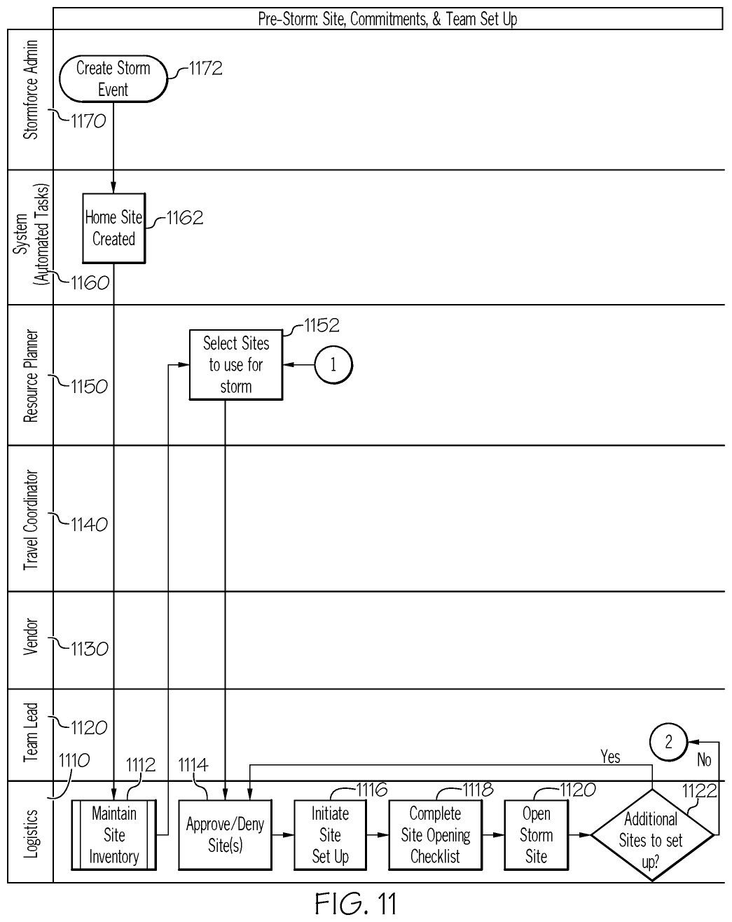

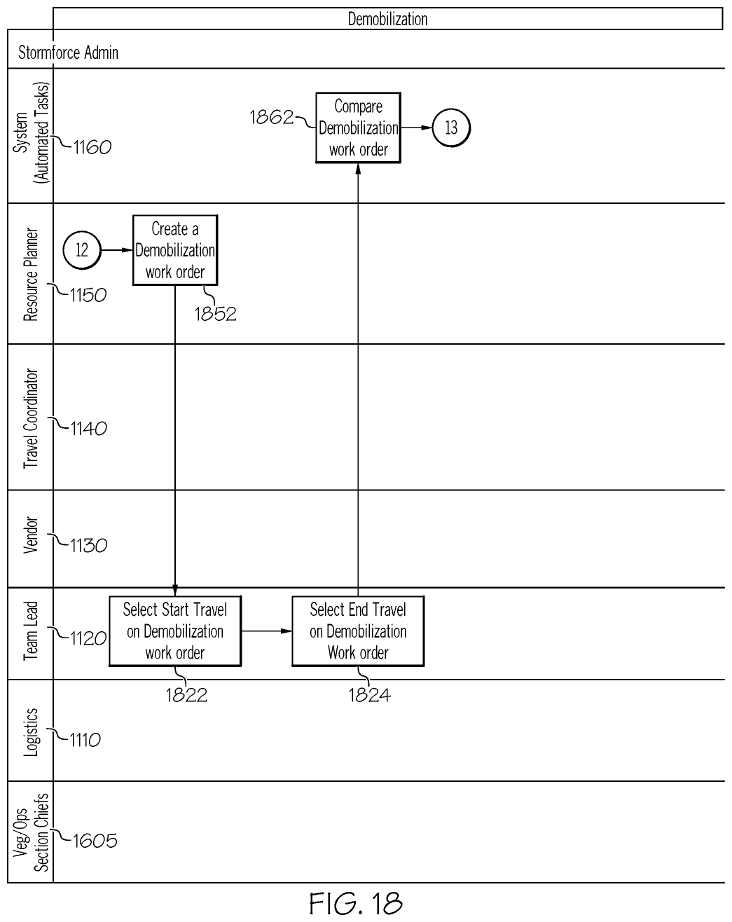

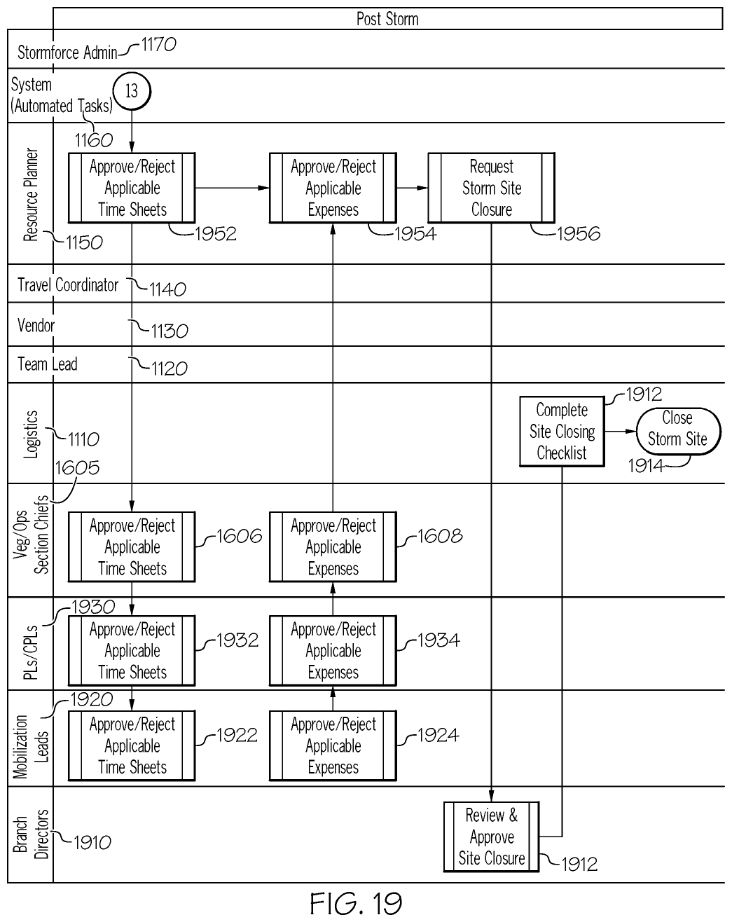

FIG. 11 through FIG. 19 is a flow of an overall process, according to an example. Shown are the processes for the overall software (i.e., StormForce) admin 1170, system (automated tasks) 1160, resource planner 1150, travel coordinator 1140, vendor 1130, team lead 1120, logistics 1110, along with section chiefs 1605 (FIG. 18) and PLs 1930, mobilization lead 1920, branch director 1910 as shown in FIG. 19.

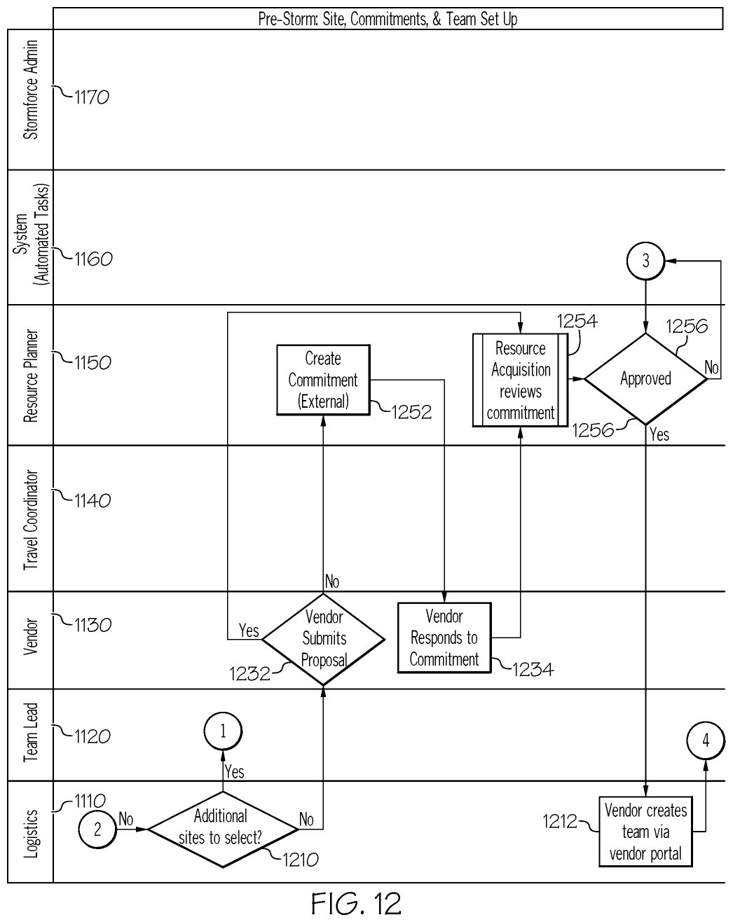

More specifically, FIG. 11 through FIG. 13 is a flow of a pre-storm, site, commitments, and team setup. The software admin 1170 opens up the software portal 250 on their electronic device, e.g., phone, tablet, laptop, or desktop computer, and navigates in the presentation module 252 over to the “create storm event” 1172. The system (automated task) creates a home site 1162, the process flows to maintain site inventory 1112, and resource planner 1150 selects sites to use for storm 1152. Logistics 1110 approves or denies sites in step 1114. The site setup is initiated 1116 along with the complete site opening checklist 1118 and storm site open 1120. A test is made if additional sites need to be set up in step 1122. In the case that additional sites need to be set up, the process returns to step 1114, as shown. Otherwise, in the event no additional sites need to be set up, the process flows to connector “2” on FIG. 12 to step 1210. In the event additional sites are selected, the process returns to connector “1” on FIG. 1, step 1152.

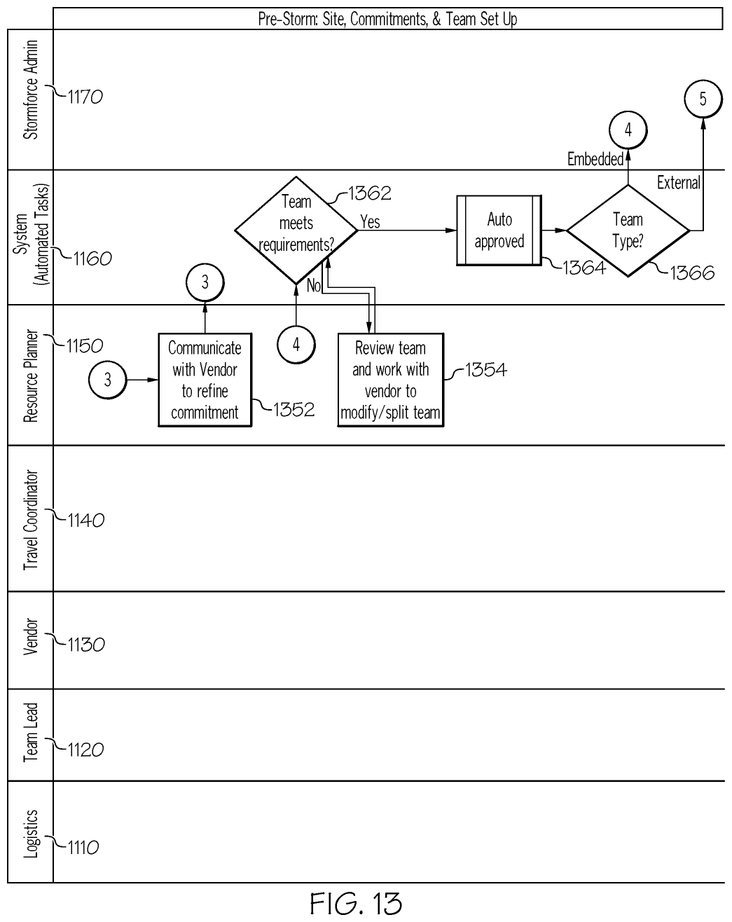

In the case that no additional sites are selected in step 1210, the process flows to the vendor submits proposal 1232. In the case that the vendor does not submit a proposal 1232, the process continues to step 1252, where the resource planner 1150 creates a commitment (external), and the vendor 1130 must respond to the commitment 1234. The process flows to step 1254, in which the resource planner 1150 reviews the commitment. Otherwise, in the case that the vendor 1130 does not submit a proposal 1232, the process flows to step 1254 as described above. The resource acquisition in step 1254 is approved or denied 1256. In the case the resource acquisition in step 1256 is not approved, the process flows to connector “3” in FIG. 13 as shown. In the case the resource acquisition in step 1256 is approved, the process continues to logistics 1110 when vendor 1130 creates the team via vendor portal 1212 as shown in FIG. 7 above, and the process flows to connector “4” in FIG. 13.

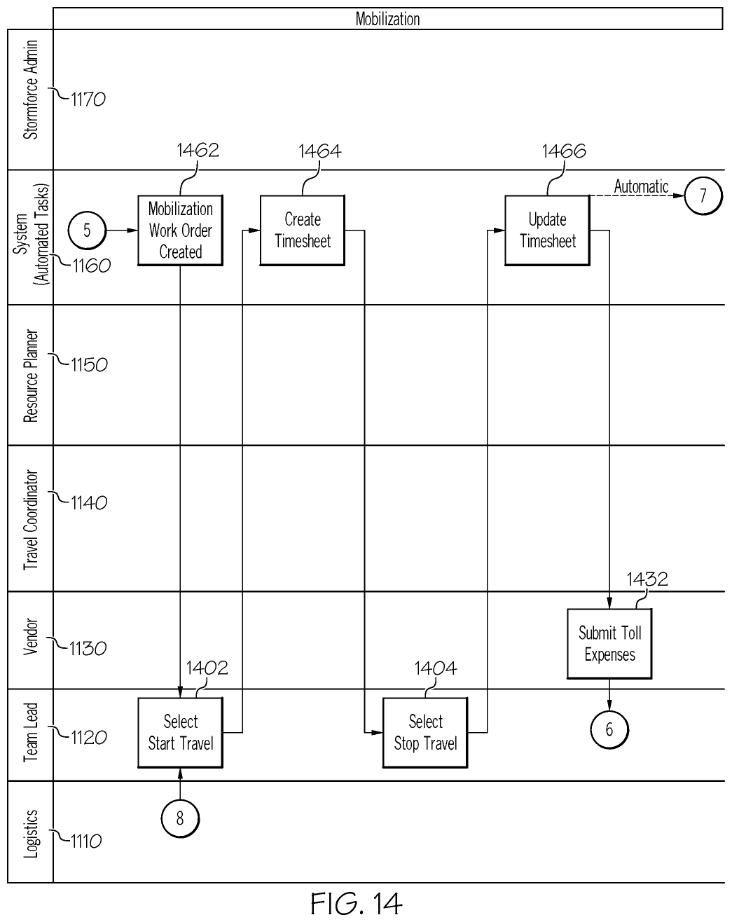

In FIG. 13, the connector “3” in step 1352 the resource planner 1150 communicates with vendor 1130 to refine commitment. Also shown in connector “4” is a system (automated tasks) 1352 determines if the team meets requirements. In the case of no, the resource planner 1150 reviews and works with the vendor to modify the team in step 1354. Once the teams meet requirements in step 1362, the system (automated tasks) auto approves in step 1364, and the team type is prompted 1366, e.g., embedded that flows to connector “4” in FIG. 13 or external which flows to connector “5” in FIG. 14.

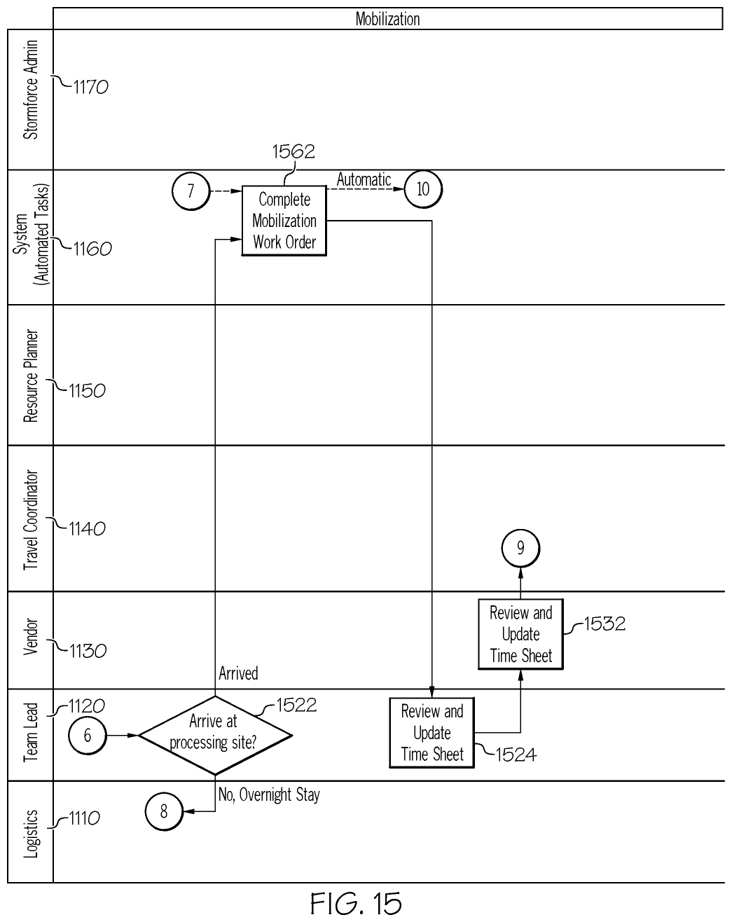

FIG. 14 through FIG. 15 is a flow of mobilization, according to an example. Stated differently, in FIG. 14 the overall system moves from “pre-storm site, commitments, and team setup” to “mobilization.” Connector “5” flows into the system (automated task) 1160 mobilization work order created 1462, and the team lead 1120 selects start travel 1402. The process returns to the system (automated tasks) 1160 to create a timesheet 1464 and then returns to the team lead 1120 to select stop travel 1404. The process continues to step 1466 update timesheet and to both connector “7” of FIG. 15 and submit toll expenses 1432 for vendor 1130 and finally to connector “6” of FIG. 15.

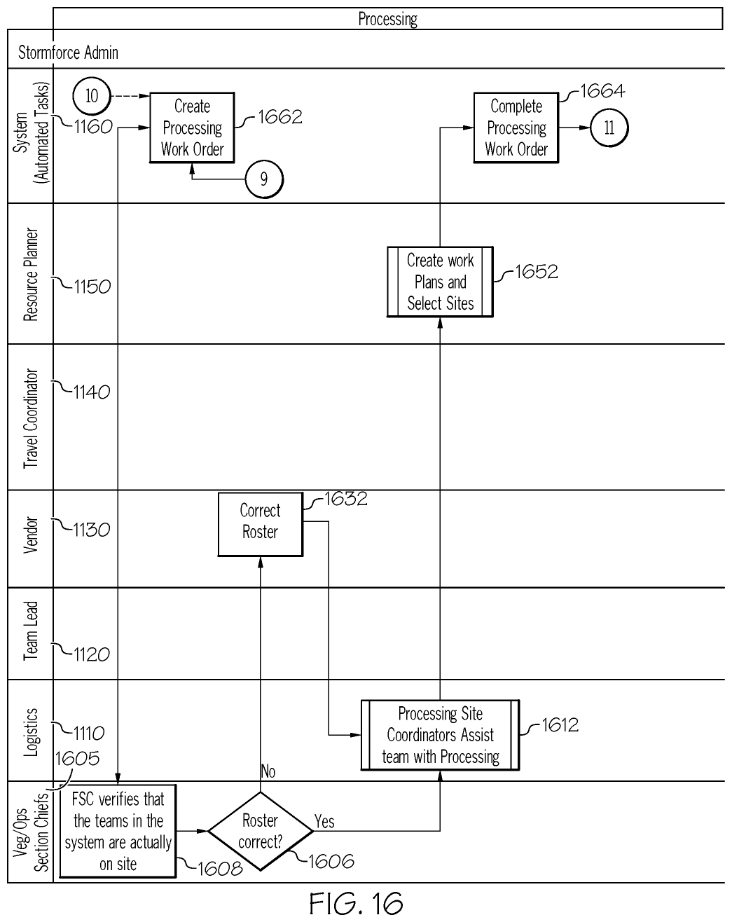

In FIG. 15, connector “6” flows into arrive at processing site 1522. If no, the process returns to logistics 1110 in connector “8”. Otherwise, at step 1522, the crew arrives, and the process flows to a system (automated task) 1160 to complete mobilization work order 1562. The process continues to connector “10” in FIG. 16 and back to team lead 1120 to review and update timesheet 1524, followed by vendor 1130 to review and update timesheet 1532 and to connector “9” in FIG. 16.

In FIG. 16, the system moves from “mobilization” to “processing.” Connector “10” flows from FIG. 15 into create processing work order 1662. In parallel, section chief 1605 verifies that the team in the system is actually on site 1608. A roster check 1606 is performed. In the case that the roster check is correct, the system proceeds to the processing site to coordinate and assist the team with processing 1612 by logistics 1110. The process flows to create work plans and select sites 1652 for the resource planner 1150, to complete processing in step 1664, and to connector “11” for FIG. 16. In the case that the roster check is incorrect, the system proceeds to work with vendor 1130 to correct the roster in step 1632 and the proceeds to step 1612 as shown.

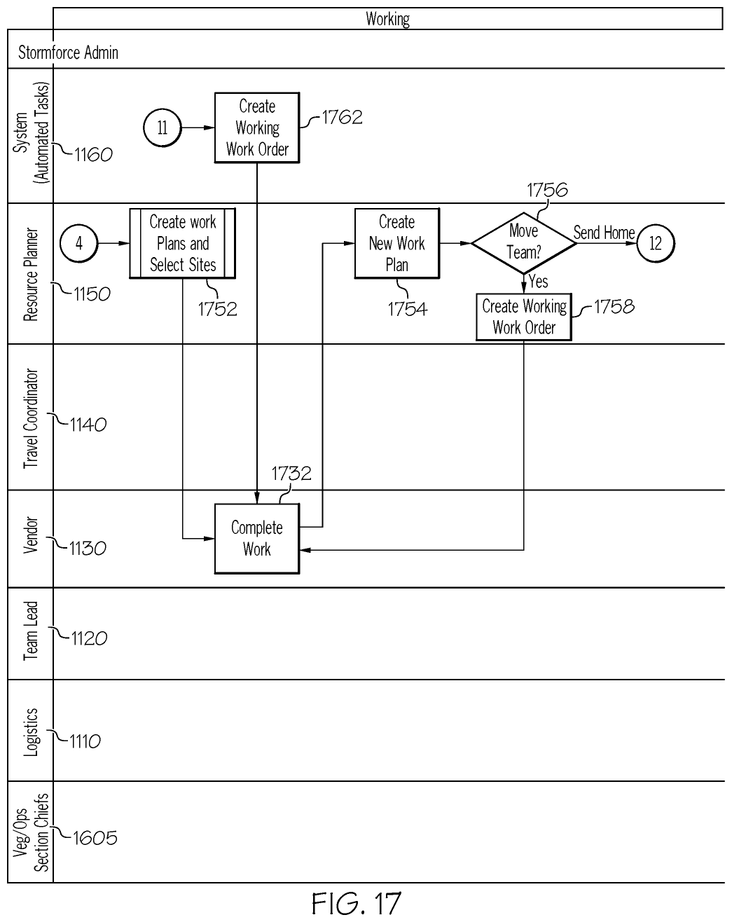

In FIG. 17, the system moves from “processing” to “working.” Connector “4” flows from FIG. 12 and FIG. 13 to create plans and select sites 1752 for resource planner 1150. Also, connector “11” from FIG. 16 flows to create working work order 1762 and then complete work 1732 as shown. The process flows to vendor 1130 to complete work 1732 and then create a new work plan 1754 for resource planner 1150. Next, a decision block to move team 1756 is performed. If the team is moved, the process continues to step 1758, create a working order, and go to vendor 1150 to complete work 1732. Otherwise, in the case the team is not moved in step 1756, the team is sent home in connector “12” of FIG. 18.

In FIG. 18, the system moves from “processing” to “demobilization.” Connector “12” flows from FIG. 17 into create demobilization work order 1852 and then to team lead 1120 to select start travel on demobilization work order 1822 and to select end travel on demobilization work order 1824. The process flows to the system (automated tasks) 1160 to compare demobilization work order 1862 to connector “13” which flows to FIG. 19.

In FIG. 19, the system moves from “demobilization” to “post-storm.” Connector “13” flows from FIG. 18 into approve/reject applicable time sheets 1952. Next, the system takes parallel paths i) to approve/reject applicable time sheets 1606, 1932, 1922 by section chiefs 1605, PLs 1930, and mobilization leads 1920 and ii) approve/reject applicable expenses 1954, 1924, 1934, 1608 by resource planner 1150, mobilization leads 1920, PLs 1930, and section chiefs 1605. The system then flows to request store site closure 1956 and branch directors 1910 to review and approve site closure 1912 and finishes with logistics 1110, completing site closing checklists and closing storm site 1954.

### Automatic Authorization to Submit Invoice

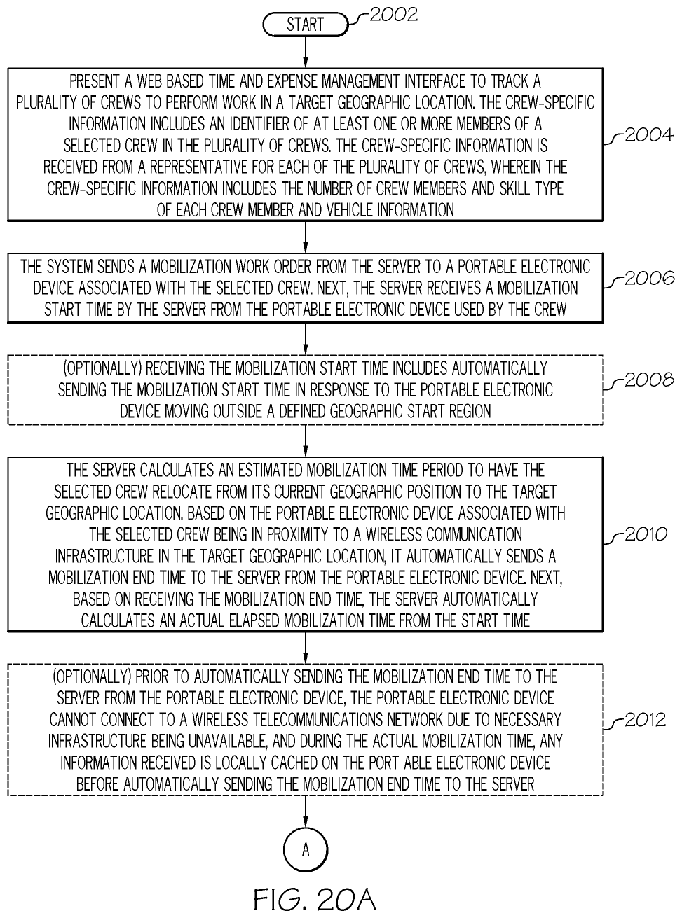

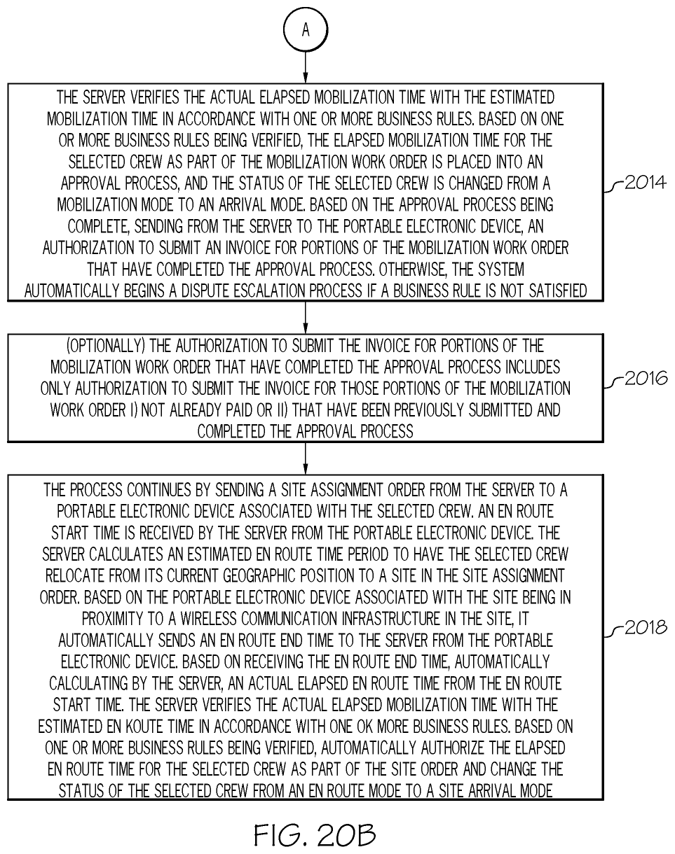

FIG. 20A and FIG. 20B is a flow of authorization to submit an invoice based on a mobilization work order. The process begins at the start 2002 and immediately proceeds to step 2004.

In step 2004, a web interface for time and expense management is presented by the server. The time and expense management interface is used to track a plurality of crews to perform work in a target geographic location. The crew-specific information includes an identifier of at least one or more members of a selected crew in the plurality of crews. The crew-specific information is received from a representative for each of the plurality of crews, wherein the crew-specific information includes the number of crew members and skill type of each crew member and vehicle information. The process continues to step 2006.

In step 2006, the system sends a mobilization work order from the server to a portable electronic device associated with the selected crew. Next, the server receives a mobilization start time by the server from the portable electronic device used by the crew. The process continues to the optional step 2008.

In optional step 2008, the step of 2006 of receiving the mobilization start time includes automatically sending the mobilization start time in response to the portable electronic device moving outside a defined geographic start region. The process continues to step 2010.

In step 2010, the server calculates an estimated mobilization time period to have the selected crew relocate from its current geographic position to the target geographic location. Based on the portable electronic device associated with the selected crew being in proximity to a wireless communication infrastructure in the target geographic location, it automatically sends a mobilization end time to the server from the portable electronic device. Next, based on receiving the mobilization end time, the server automatically calculates an actual elapsed mobilization time from the start time. The process continues to the optional step 2012.

In optional step 2012, prior to automatically sending the mobilization end time to the server from the portable electronic device, the portable electronic device cannot connect to a wireless telecommunications network due to necessary infrastructure being unavailable, and during the actual mobilization time, any information received is locally cached on the portable electronic device before automatically sending the mobilization end time to the server. The process continues to the optional step 2014.

In step 2014, the server verifies the actual elapsed mobilization time with the estimated mobilization time in accordance with one or more business rules. Based on one or more business rules being verified, the elapsed mobilization time for the selected crew as part of the mobilization work order is placed into an approval process, and the status of the selected crew is changed from a mobilization mode to an arrival mode. Based on the approval process being complete, sending from the server to the portable electronic device, an authorization to submit an invoice for portions of the mobilization work order that have completed the approval process. Otherwise, the system automatically begins a dispute escalation process if a business rule is not satisfied. The process continues to the optional step 2016.

In optional step 2016, the authorization to submit the invoice for portions of the mobilization work order that have completed the approval process includes only authorization to submit the invoice for those portions of the mobilization work order i) not already paid or ii) that have been previously submitted and completed the approval process. The process continues to the optional step 2018.

The present invention helps to document time and expense for government agencies, such as public utility commissions. This documentation is often used to assist with setting special charges on customer invoices.

Next, in step 2018, the process continues by sending a site assignment order from the server to a portable electronic device associated with the selected crew. An en-route start time is received by the server from the portable electronic device. The server calculates an estimated en route time period to have the selected crew relocate from its current geographic position to a site in the site assignment order. Based on the portable electronic device associated with the site being in proximity to a wireless communication infrastructure in the site, it automatically sends an en route end time to the server from the portable electronic device. Based on receiving the en route end time, automatically calculated by the server, an actual elapsed en route time from the en route start time. The server verifies the actual elapsed mobilization time with the estimated en route time in accordance with one or more business rules. Based on one or more business rules being verified, automatically authorize the elapsed en route time for the selected crew as part of the site order and change the status of the selected crew from an en route mode to a site arrival mode. The process proceeds to step 2020 to end.

### Interactive User Interface

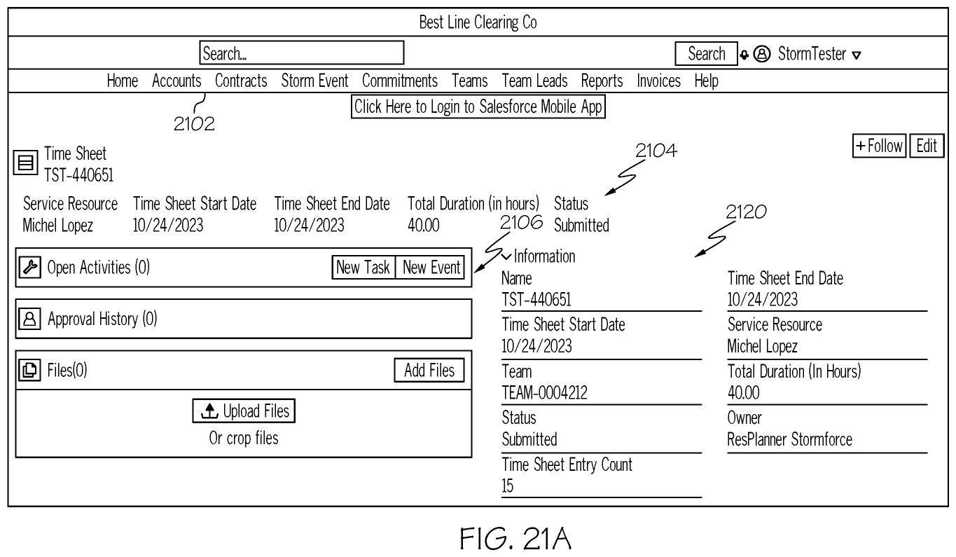

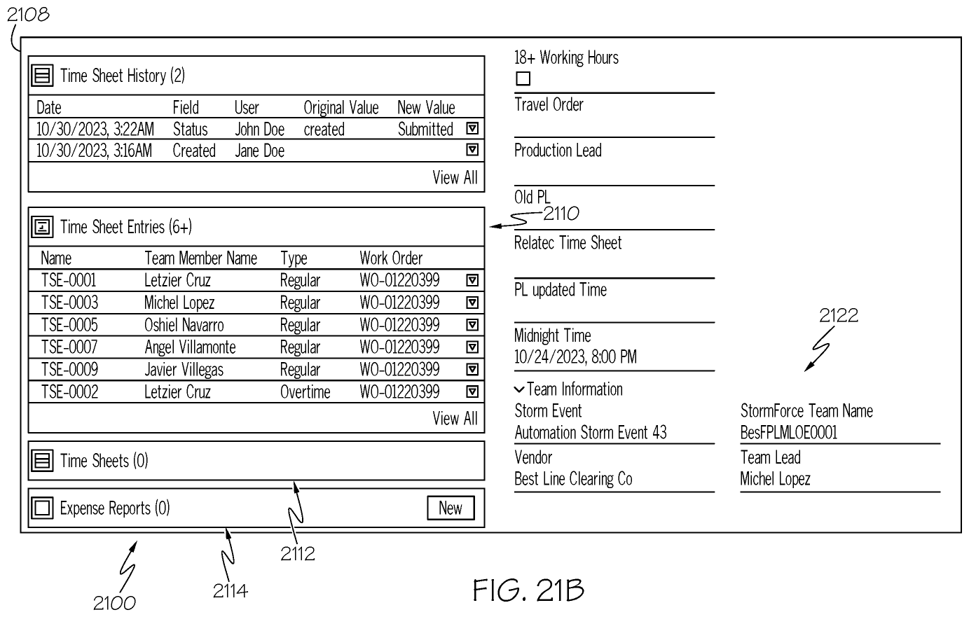

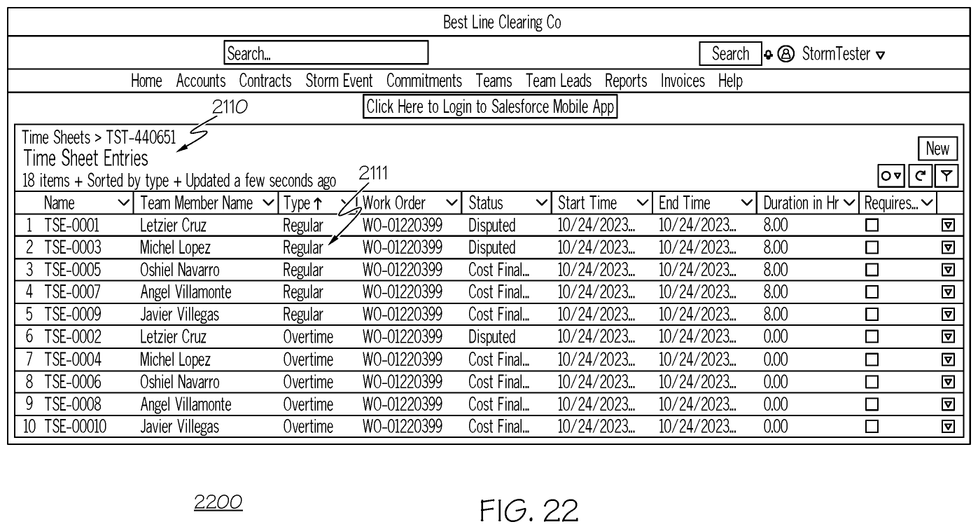

Turning now to FIG. 21A, FIG. 21B and FIG. 22 are interactive user-interface screens 2100 and 2200 of the time and entry process of FIG. 1-20, according to an example. The interactive nature of this user-interface provides real-time information to the vender as wall A vendor, in this example named “Best Line Clearing Co.” Section 2102 shows a variety of navigation destinations in section 2102 as a top tool bar entitled “Home”, “Accounts”, “Contacts”, “Storm Event”, “Commitments”, “Teams”, “Teams/Pads”, “Reports”, “Invoices”, “Help” and a “Seach” button on top. Section 2104 contains important information, including dates for invoicing.

Beginning with the left-side of this user interface 2100, section 2106 illustrates a status area of various activities, including “Open Activities”, “Approval History”, “Files” that were uploaded.

Section 2108 illustrates a listing of Time Sheets with the “Date”, “User”, “Original Value (or status)” and “New Value or status” as shown.

Section 2110 illustrates sheet entries of the crew with the “Crew Member Name”, “Type of Time,” e.g., regular overtime, travel time, etc. Section 2112 is a timesheet currently being edited and revised.

Section 2114 the corresponding expense reports for any time sheet.

Referring to the right side of this user interface 2100, section 2120 is information about the current timesheet, e.g. “Name”, “Start Date”, “End Date”, “Total Hours”, “Number of Time Sheet Entry Count”, “Working Hours”, “Travel order, “Production lead” and “Midnight Time.”

Section 2122 is the crew or team information, including “Vendor Name, “Team Lead”, “Team Name” followed by “System Information”.

Referring to FIG. 22, shown is a user interface 2200 illustrating more details of section 2110 when selected by the vendor. Shown are time sheet “Name”, “Team Member Name”, “Type”, “Work Order”, “Status”, “Start Time”, “End Time” and “Duration” as shown.

### Portable Electronic or Handheld Device

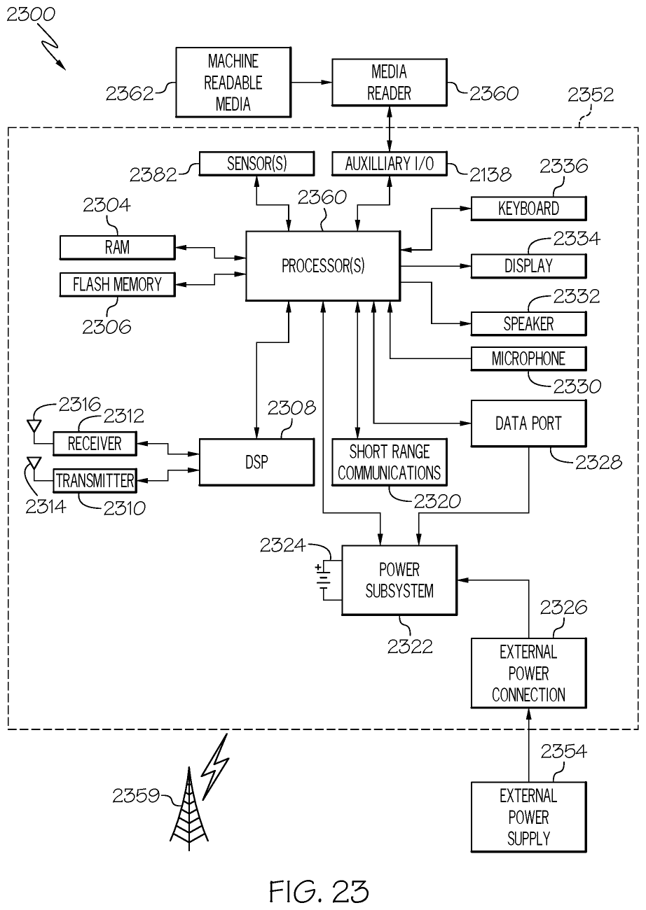

FIG. 23 is a block diagram of an example of a portable electronic or handheld device 2300 that includes two-way wireless communications functions. Such handheld devices incorporate communication subsystem elements such as a wireless transmitter 2310, a wireless receiver 2312, and associated components such as one or more antenna elements 2314 and 2316. A digital signal processor (DSP) 2308 performs processing to extract data from received wireless signals and to generate signals to be transmitted. The particular design of the communication subsystem is dependent upon the communication network and associated wireless communications protocols with which the device is intended to operate.

The handheld device 2300 includes a microprocessor 2302 that controls the overall operation of the handheld device 2352. The microprocessor 2302 interacts with the above-described communications subsystem elements and also interacts with other device subsystems such as non-volatile or flash memory 2306, random access memory (RAM) 2304, auxiliary input/output (I/O) device 2338, data port 2328, display 2334, keyboard 2336, speaker 2332, microphone 2330, a short-range communications subsystem 2320, a power subsystem 2322, and or any other device subsystems.

One or more sensors 2382 are incorporated into or coupled with handheld device. The sensor 2382 is operative to sense such movement by any sensing device currently known and understood within the relevant art, or hereinafter invented. Examples of sensor 2382 include one or more accelerometers, Global Positioning System (GPS), G-force meter, gravimeter, gradiometer, inclinometer, clinometer, tiltmeter, micro electro-mechanical system (MEMS), compass, or the like, using any known technology, including liquid capacitive, piezoelectric, piezoresistive, piezoceramic, or other technology currently known and understood within the relevant art, or hereinafter invented. Such devices or technology enable the conversion of movement information to an electric signal that is interpreted by microprocessor 2302.

Pairs or triplet combinations, or bi-axial or tri-axial implementations of sensor 2382 may are used for detecting movement in two or three dimensions. Sampling rates of sensor 2382 are selected to balance cost and other factors, with a requirement for the perception of responsiveness and smooth movement desired for a user. One or more accelerometers may provide information regarding a rate of speed or acceleration of a handheld device, and may also provide information pertaining to the orientation of the handheld device 2300, as well. Algorithms or software which may be executed by microprocessor 2302, for converting spatial, coordinate, or other reference information embedded within such electric signal, to an angular orientation of the sensing device and/or an orientation of a device into which the sensing device is connected or associated, is understood by one skilled in the relevant art.

A battery 2324 is connected to a power subsystem 2322 to provide power to the circuits of the handheld device 2352. The power subsystem 2322 includes power distribution circuitry for providing power to the handheld device 2300 and also contains battery charging circuitry to manage recharging the battery 2324. The power subsystem 2322 includes a battery monitoring circuit that is operable to provide status of one or more battery status indicators, such as remaining capacity, temperature, voltage, electrical current consumption, and the like, to various components of the electronic handheld 2300. There may be an external power connector 2326 electrically coupled to an external power supply 2354 as shown.

The data port 2328 is able to support data communications between the handheld device 2300 and other devices through various modes of data communications, such as high speed data transfers over optical communications circuits or over electrical data communications circuits such as a USB connection incorporated into the data port 2328 of some examples. Data port 2328 is able to support communications with, for example, an external computer or other device.

Data communication through data port 2328 enables a user to set preferences through the external device or through a software application and extends the capabilities of the device by enabling information or software exchange through direct connections between the handheld device 2352 and external data sources rather than via a wireless data communication network 2359. In addition to data communication, the data port 2328 provides power to the power subsystem 2322 to charge the battery 2324 or to supply power to the electronic circuits, such as microprocessor 2302, of the handheld device 2300.

Operating system software used by the microprocessor 2302 is stored in flash memory 2306. Further examples are able to use a battery backed-up RAM or other non-volatile storage data elements to store operating systems, other executable programs, or both. The operating system software, device application software, or parts thereof, are able to be temporarily loaded into volatile data storage such as RAM 2304. One example of data storage in RAM is time and expense environment 250. Data received via wireless communication signals or through wired communications are also able to be stored to RAM 2304.

The microprocessor 2302, in addition to its operating system functions, is able to execute software applications on the handheld device 2300. A predetermined set of applications that control basic device operations, including at least data and voice communication applications, is able to be installed on the handheld device 2300 during manufacture. Examples of applications that are able to be loaded onto the device may be a personal information manager (PIM) application having the ability to organize and manage data items relating to the device user, such as, but not limited to, email, calendar events, voice mails, appointments, and task items.

Further applications may also be loaded onto the handheld device 2300 through, for example, the wireless network 2350, an auxiliary I/O device 2338, data port 2328, short-range communications subsystem 2320, or any combination of these interfaces. Such applications are then able to be installed by a user in the RAM 2304 or a non-volatile store for execution by the microprocessor 2302.

In a data communication mode, a received signal such as a text message or web page download is processed by the communication subsystem, including wireless receiver 2312 and wireless transmitter 2310, and communicated data is provided the microprocessor 2302, which is able to further process the received data for output to the display 2334, or alternatively, to an auxiliary I/O device 2338 or the data port 2328. A user of the handheld device 2352 may also compose data items, such as email messages, using the keyboard 2336, which is able to include a complete alphanumeric keyboard or a telephone-type keypad, in conjunction with the display 2334 and possibly an auxiliary I/O device 2338. Such composed items are then able to be transmitted over a communication network through the communication subsystem.

For voice communications, overall operation of the handheld device 2300 is substantially similar, except that received signals are generally provided to a speaker 2332 and signals for transmission are generally produced by a microphone 2330. Alternative voice or audio I/O subsystems, such as a voice message recording subsystem, may also be implemented on the handheld device 2300. Although voice or audio signal output is generally accomplished primarily through the speaker 2332, the display 2334 may also be used to provide an indication of the identity of a calling party, the duration of a voice call, or other voice call related information, for example.

Depending on the conditions or statuses of the handheld device 2300, one or more particular functions associated with a subsystem circuit may be disabled, or an entire subsystem circuit may be disabled. For example, if the battery temperature is low, then voice functions may be disabled, but data communications, such as email, may still be enabled over the communication subsystem.

A short-range communications subsystem 2320 provides for data communication between the handheld device 2352 and different systems or devices, which need not necessarily be similar devices. For example, the short-range communications subsystem 2320 includes an infrared device and associated circuits and components or a Radio Frequency based communication module such as one supporting Bluetooth® communications, to provide for communication with similarly-enabled systems and devices, including the data file transfer communications described above.

A media reader 2360 is able to be connected to an auxiliary I/O device 2338 to allow, for example, loading computer readable program code of a computer program product into the handheld device 2300 for storage into non-volatile memory such as flash memory 2306. One example of a media reader 2360 is an optical drive such as a CD/DVD drive, which may be used to store data to and read data from a computer readable medium or storage product such as computer readable storage media 2362. Examples of suitable computer readable storage media include optical storage media such as a CD or DVD, magnetic media, or any other suitable data storage device. Media reader 2360 is alternatively able to be connected to the electronic device through the data port 2328 or computer readable program code is alternatively able to be provided to the handheld device 2300 through the wireless network 2350.

### Incorporated Reference

U.S. Pat. No. 11,556,872, entitled, “Time And Expense Tracking System,” inventors Molly CARTY et al. and commonly assigned herewith, is hereby incorporated by reference in its entirety.

### Non-Limiting Examples

Although specific examples of the subject matter have been disclosed, those having ordinary skill in the art will understand that changes can be made to the specific examples without departing from the spirit and scope of the disclosed subject matter. The scope of the disclosure is not to be restricted, therefore, to the specific examples, and it is intended that the appended claims cover any and all such applications, modifications, and examples within the scope of the present disclosure.

What is claimed is:

1. A computer-implemented method for time and expense management, the method comprising:
operating on a server, a time and expense management interface to track a plurality of crews to perform work in a target geographic location, wherein the crew is associated with crew-specific information including an identifier of at least one or more members of a selected crew in the plurality of crews;
sending a mobilization work order from the server to a portable electronic device associated with the selected crew;
receiving a mobilization start time by the server from the portable electronic device; calculating by the server, an estimated mobilization time period to have the selected crew relocate from its current geographic position to the target geographic location;
based on the portable electronic device associated with the selected crew being in proximity to a wireless communication infrastructure in the target geographic location, automatically sending a mobilization end time to the server from the portable electronic device; based on receiving the mobilization end time, automatically calculating by the server an actual elapsed mobilization time from the start time;
verifying by the server the actual elapsed mobilization time with the estimated mobilization time in accordance with one or more business rules;
based on the one or more business rules being verified, placing the elapsed mobilization time for the selected crew as part of the mobilization work order into an approval process, and changing a status of the selected crew from a mobilization mode to an arrival mode; and
based on the approval process being complete, sending from the server to the portable electronic device, an authorization to submit an invoice for portions of the mobilization work order which have completed the approval process.

2. The computer-implemented method of claim 1, wherein prior to automatically sending the mobilization end time to the server from the portable electronic device, the portable electronic device cannot connect to a wireless telecommunications network due to necessary infrastructure being unavailable, and during the actual mobilization time any information received is locally cached on the portable electronic device before automatically sending the mobilization end time to the server.

3. The computer-implemented method of claim 1, wherein the receiving the mobilization start time includes automatically sending the mobilization start time in response to the portable electronic device moving outside a defined geographic start region.

4. The computer-implemented method of claim 1, wherein the crew-specific information is received from a representative for each of the plurality of crews, wherein the crew-specific information includes a number of crew members and skill type of each crew member and vehicle information.

5. The computer-implemented method of claim 1, wherein the sending from the server to the portable electronic device, the authorization to submit the invoice for portions of the mobilization work order which have completed the approval process includes only authorization to submit the invoice for those portions of the mobilization work order i) not already paid or ii) that have been previously submitted and completed the approval process.

6. The computer-implemented method of claim 1, further comprising:
sending a site assignment order from the server to a portable electronic device associated with the selected crew;
receiving an en route start time by the server from the portable electronic device;
calculating by the server, an estimated en route time period to have the selected crew relocate from its current geographic position to a site in the site assignment order;
based on the portable electronic device associated with the site being in proximity to a wireless communication infrastructure in the site, automatically sending an en route end time to the server from the portable electronic device;
based on receiving the en route end time, automatically calculating by the server an actual elapsed en route time from the en route start time;
verifying by the server the actual elapsed mobilization time with the estimated en route time in accordance with one or more business rules; and
based on the one or more business rules being verified, automatically authorizing the elapsed en route time for the selected crew as part of the site order and changing the status of the selected crew from an en route mode to a site arrival mode.

7. The computer-implemented method of claim 4, further comprises:
beginning a dispute escalation process if a business rule is not satisfied.

8. The computer-implemented method of claim 3, wherein the crew-specific information is received from a representative for each of the plurality of crews, wherein the crew-specific information includes the number of crew members and skill type of each crew member and vehicle information and a personal identifier of each crew member using one of
a facial recognition;
fingerprint recognition;
a near-field communication tags; or
a combination thereof.

9. The computer-implemented method of claim 3, wherein the crew-specific information is received from a representative for each of the plurality of crews, wherein the crew-specific information includes receiving an identification of a vehicle assigned to the crew; and
wherein the one or more business rules being verified include verifying the identification of a vehicle to an authorized vehicle.

10. The computer-implemented method of claim 3, wherein the crew-specific information is received from a representative for each of the plurality of crews, wherein the crew-specific information includes body temperature and wellness information of the crew to reduce transmission of a virus to predefined thresholds.

11. The computer-implemented method of claim 1, further comprising:
receiving, by the server from the portable electronic device, at least one expense entry for the at least one or more members of the selected crew, the expense entry including an image of a receipt corresponding to the expense entry;
performing text recognition on the receipt to identify one or more items, each with a corresponding price;
adding the corresponding price of the one or more items on the receipt to calculate a total; comparing the total with the expense entry; and
based on the expense entry being less than or equal to the total, applying business rules to the expense entries.

12. A system for time and expense management, the system comprising:
a memory with program instructions;
a processor communicatively coupled to the memory, wherein the program instructions, when executed by the processor is configured to cause the processor to perform the steps of
operating on a server, a time and expense management interface to track a plurality of crews to perform work in a target geographic location, wherein the crew is associated with crew-specific information including an identifier of at least one or more members of a selected crew in the plurality of crews;
sending a mobilization work order from the server to a portable electronic device associated with the selected crew;
receiving a mobilization start time by the server from the portable electronic device; calculating by the server, an estimated mobilization time period to have the selected crew relocate from its current geographic position to the target geographic location;
based on the portable electronic device associated with the selected crew being in proximity to a wireless communication infrastructure in the target geographic location, automatically sending a mobilization end time to the server from the portable electronic device; based on receiving the mobilization end time, automatically calculating by the server an actual elapsed mobilization time from the start time;
verifying by the server the actual elapsed mobilization time with the estimated mobilization time in accordance with one or more business rules;
based on the one or more business rules being verified, placing the elapsed mobilization time for the selected crew as part of the mobilization work order into an approval process, and changing a status of the selected crew from a mobilization mode to an arrival mode; and
based on the approval process being complete, sending from the server to the portable electronic device, an authorization to submit an invoice for portions of the mobilization work order which have completed the approval process.

13. The system of claim 12, wherein prior to automatically sending the mobilization end time to the server from the portable electronic device, the portable electronic device cannot connect to a wireless telecommunications network due to necessary infrastructure being unavailable, and during the actual mobilization time any information received is locally cached on the portable electronic device before automatically sending the mobilization end time to the server.

14. The system of claim 12, wherein the receiving the mobilization start time includes automatically sending the mobilization start time in response to the portable electronic device moving outside a defined geographic start region.

15. The system of claim 12, wherein the crew-specific information is received from a representative for each of the plurality of crews, wherein the crew-specific information includes a number of crew members and skill type of each crew member and vehicle information.

16. The system of claim 12, wherein the sending from the server to the portable electronic device, the authorization to submit the invoice for portions of the mobilization work order which have completed the approval process includes only authorization to submit the invoice for those portions of the mobilization work order i) not already paid or ii) that have been previously submitted and completed the approval process.

17. The system of claim 12, further comprising:
sending a site assignment order from the server to a portable electronic device associated with the selected crew;
receiving an en route start time by the server from the portable electronic device;
calculating by the server, an estimated en route time period to have the selected crew relocate from its current geographic position to a site in the site assignment order;
based on the portable electronic device associated with the site being in proximity to a wireless communication infrastructure in the site, automatically sending an en route end time to the server from the portable electronic device;
based on receiving the en route end time, automatically calculating by the server an actual elapsed en route time from the en route start time;
verifying by the server the actual elapsed mobilization time with the estimated en route time in accordance with one or more business rules; and
based on the one or more business rules being verified, automatically authorizing the elapsed en route time for the selected crew as part of the site order and changing the status of the selected crew from an en route mode to a site arrival mode.

18. The system of claim 15, further comprises:
beginning a dispute escalation process if a business rule is not satisfied.

19. The system of claim 14, wherein the crew-specific information is received from a representative for each of the plurality of crews, wherein the crew-specific information includes the number of crew members and skill type of each crew member and vehicle information and a personal identifier of each crew member using one of
a facial recognition;
fingerprint recognition;
a near-field communication tags; or
a combination thereof.

20. The system of claim 12, wherein the crew-specific information is received from a representative for each of the plurality of crews, wherein the crew-specific information includes receiving an identification of a vehicle assigned to the crew; and
wherein the one or more business rules being verified include verifying the identification of a vehicle to an authorized vehicle.
